(19) United States
(12) Patent Application Publication
(10) Pub. No.: US 2015/0171250 A1
(43) Pub. Date: Jun. 18, 2015

(54) COOLING SYSTEM FOR A SOLAR POWER GENERATOR

(71) Applicant: SOLAR SYSTEMS PTY LTD, Abbotsford, Victoria (AU)

(72) Inventor: Malcolm Heys, Eltham (AU)

(21) Appl. No.: 14/411,748

(22) PCT Filed: Jun. 28, 2013
(86) PCT No.: PCT/AU2013/000718

§ 371 Date: Dec. 29, 2014

Related U.S. Application Data
(60) Provisional application No. 61/665,892, filed on Jun. 29, 2012.

(51) Int. Cl. H01L 31/052; H02S 40/42; H02S 40/22; H01L 31/054

(52) U.S. Cl. CPC H01L 31/052; H01L 31/0547; H02S 40/42; H02S 40/22

(57) ABSTRACT

A solar power generator is presented. In an embodiment, the solar power generator includes: a receiver that includes one or more photovoltaic cells for converting concentrated solar radiation into electrical energy, a solar concentrator that includes an array of mirrors for concentrating solar radiation on the receiver, a frame on which the mirrors are mounted, the frame including one or more support arms for supporting the receiver relative to the solar concentrator, and a cooling system including a cooling circuit for cooling the photovoltaic cells with a coolant, and cooling system components including a reservoir and one or more heat exchangers, wherein the reservoir and one or more heat exchangers are mounted on the frame. A method of installing a cooling system for a solar power generator is also presented.

This International patent application claims priority from U.S. Patent Application Ser. No. 61/665,892 filed on 29 Jun. 2012 the contents of which are herein incorporated by this reference.

### FIELD OF THE INVENTION

The present invention relates to a solar power generator and a method of installing a cooling system for a solar power generator. The present invention has applicability in concentrated solar power systems.

### BACKGROUND OF THE INVENTION

A concentrated solar power system includes a receiver and a solar concentrator. The solar concentrator reflects light incident on a relatively large surface area of the solar concentrator to a relatively small surface area of the receiver.

The receiver and solar concentrator may take many different forms. For example, the solar concentrator may be a dish reflector that includes a parabolic array of mirrors that reflect light towards the receiver. The receiver may include a dense array of photovoltaic modules which convert the light to electrical energy. The solar concentrator may alternatively be a series of flat mirrors attached to a frame and angled to reflect solar radiation onto a solar energy receiver. The receiver may include only a single photovoltaic cell.

One issue associated with the development of concentrated solar power systems is the long term performance of components of the system. Factors such as exposure to concentrated solar radiation, cycling in temperature and mismatch between coefficients of thermal expansion of materials of the components may cause the components to degrade over time. This is especially the case in the receiver, which may be exposed to 500 or more times the normal sunlight.

The performance of a photovoltaic receiver may fall by around 1.7% for every 10° C. rise in cell temperature. Operating the receiver at a lower temperature may result in higher conversion efficiencies and power extraction. Therefore, effective cooling of the receiver is important to achieve efficient performance.

An issue with the development of cooling systems for concentrated solar power systems is the ongoing cost in terms of power consumption of the cooling system. The amount of power used by the cooling system impacts on the generation capacity of the overall power system. Another issue with the development of cooling systems is the overall cost of the system. This includes cost to manufacture or purchase the components of the system, and cost to maintain and repair these components over the life of the solar power generator.

For solar power systems to be competitive with traditional means of generating electricity, the Levelized Cost of Energy (LCOE) for generating solar energy needs to be competitive with the LCOE of traditional systems. The LCOE is based on a combination of three factors—power plant capital cost, system operating and maintenance cost and energy generation over the plant lifetime.

It would be desirable to provide a solar power generator with an alternative cooling system to existing solar power generators that addresses one or more of the issues described above.

The above discussion of background art is included to explain the context of the present invention. It is not to be taken as an admission that any of the documents or other material referred to was published, known or part of the common general knowledge at the priority date of any one of the claims of this specification.

### SUMMARY OF THE INVENTION

The present invention provides a solar power generator including: a receiver that includes one or more photovoltaic cells for converting concentrated solar radiation into electrical energy, a solar concentrator that includes an array of mirrors for concentrating solar radiation on the receiver, a frame on which the mirrors are mounted, the frame including one or more support arms for supporting the receiver relative to the solar concentrator, and a cooling system including a cooling circuit for cooling the photovoltaic cells with a coolant, and cooling system components including a reservoir and one or more heat exchangers, wherein the reservoir and one or more heat exchangers are mounted on the frame.

The present invention also provides a method of installing a cooling system for a solar power generator including a receiver that includes one or more photovoltaic cells for converting concentrated solar radiation into electrical energy, a solar concentrator that includes an array of mirrors for concentrating solar radiation on the receiver, and a frame on which the mirrors are mounted, the frame including one or more support arms for supporting the receiver in a fixed position relative to the solar concentrator, the method including: mounting a reservoir on the frame, mounting one or more heat exchangers on the frame, and connecting these components with a cooling circuit for cooling the photovoltaic cells with a coolant.

By mounting the reservoir and one or more heat exchangers on the frame of the solar power generator, the overall cost of the cooling system may be reduced. Mounting the components on the frame may reduce the length of piping and other assemblies needed to connect the cooling system components with the coolant flow paths in the receiver for cooling the photovoltaic cells. Also, because the amount of piping required is reduced, the size and capacity of the components of the cooling system may also be correspondingly reduced. For example, smaller heat exchangers may have sufficient capacity to extract heat from the coolant, and smaller pumps may have sufficient capacity to move the coolant through the cooling circuit. This may reduce the cost of components required, as well as reduce the power consumption of the cooling system.

The maintenance requirements of the cooling system of the present invention may also be reduced compared with prior art solar power generators. In the present invention, the reservoir and one or more heat exchangers of the cooling system are stationary relative to each other as the solar concentrator moves to track the path of the sun. Therefore, flexible hoses are not required to connect these components and build the cooling system. This may reduce wear on the cooling circuit pipes, reducing the amount of maintenance time and, resources required to maintain the cooling system.

The receiver may be any type of photovoltaic receiver, as would be understood by the skilled addressee. The photovoltaic cells may be single or multi junction cells, and in the case of more than one photovoltaic cell, may be electrically connected in series, parallel or a combination of series and parallel. The cells may be arranged in a two dimensional array, in abutting relationship on a curved substrate, on a multi-surface substrate such as a cube or in a linear dense array of cells.

The solar concentrator may contain any arrangement of mirrors to concentrate light on the receiver. For example, the solar concentrator may be a dish reflector that includes a parabolic array of mirrors that reflect light towards the receiver. The concentrator may alternatively include an array of flat mirrors attached to a frame. In another example, the array of mirrors may be an arranged in a hemispherical configuration.

The cooling circuit of the cooling system may include a coolant flow path that is in thermal contact with the one or more photovoltaic cells so that in use coolant flowing through the flow path extracts heat from the photovoltaic cells and thereby cools the cells. The coolant flow path may be designed to travel through one or more heat sinks associated with the one or more photovoltaic cells and through one or more support arms of the frame.

The cooling system components may be any components suitable for extracting heat from the photovoltaic cells. For example, the one or more heat exchangers may each include a radiator and fan, for removing heat from the cooling circuit. The reservoir may be any container or receptacle for allowing expansion and contraction of the coolant due to temperature fluctuations. For example, the reservoir may be a cylindrical or other shape container made of ceramic, plastic or metal such as steel. Any suitable coolant may be used in the system. For example, the coolant may be water and may include additives such as glycol and corrosion inhibitors.

The frame may include a support mast, which is firmly fixed into the ground, a mirror frame for securing the mirrors to reflect solar radiation onto the receiver, and support arms for supporting the receiver relative to the mirrors. The frame may also include other components such as a tracking mechanism having a vertical axis and a horizontal axis about which the solar concentrator is rotatable, to enable movement of the frame to point the mirrors towards the sun for the majority of the daylight hours. The cooling system components may be mounted on the frame by any means, such as bolting, tying, taping, fastening, or any other means.

The frame may include any number of support arms for supporting the receiver relative to the solar concentrator. In one example, the receiver may be supported by four support arms extending from four positions on the frame 90 degrees apart. In another example, the receiver may be supported by a single support arm. The support arms may, for example, be straight or curved struts.

The support arms for supporting the receiver may include a lower support arm, which extends from a low position on the frame. The lower support arm may extend from a lowest region of the solar concentrator, or from any other region in a lower half of the solar concentrator. The reservoir may be mounted on the lower support arm. To allow expansion of the coolant (due to heating and cooling), a nitrogen blanket may be injected into the reservoir, above the coolant. Nitrogen is an abundant, inert gas that prevents corrosion inside of the reservoir while allowing for expansion and contraction of the coolant due to temperature fluctuations. Other gases or air may alternatively be used to provide an expansion buffer in the reservoir.

By mounting the reservoir on the lower support arm, the nitrogen or other gas blanket in the reservoir may be prevented from entering the cooling circuit despite movement of the frame about a horizontal and vertical axis. Depending on the latitude of the solar generator, the frame may undergo movement of up to 120 degrees around the horizontal axis. With this range of movement, there is a risk that a reservoir mounted on the frame would allow leakage of gas into the coolant, reducing the cooling system's effectiveness. Mounting the reservoir on the lower support arm reduces this risk and thus may assist in maintaining the efficiency of the system.

Another advantage of mounting the reservoir on the lower support arm is ease of access from the ground. When performing maintenance on the cooling system, operators may be able to access the reservoir without the need for long ladders, lifts or cranes. Conveniently, the nitrogen injector may be located near the reservoir for ease of operation and refilling.

The lower support arm may extend from a lower part of the frame to the receiver at an angle of about 45 degrees to a line extending from a middle of the frame to the receiver. This may facilitate preventing gas leakage from the reservoir into the cooling circuit. For example, if the solar concentrator is tilted 5.5 degrees downward from horizontal, the reservoir would extend in a direction 39.5 degrees upward from horizontal. Similarly, if the solar concentrator is tilted 78 degrees upward from horizontal, the reservoir would extend in a direction 33 degrees upward from horizontal. Thus, although the solar concentrator may be rotated downwards and upwards from the horizontal, the gas in the reservoir may still remain above the coolant. It will be appreciated that the lower support arm may extend at different angles than 45 degrees and still enable a mounted reservoir to rotate without gas leakage.

The reservoir may be elongate, with a long axis of the reservoir being parallel to the lower support arm. This may further facilitate the prevention of gas leakage from the reservoir, as the level of the coolant is less likely to drop to such an extent that it exposes a coolant circuit feed-in pipe to gas in the reservoir. The reservoir need not be elongate, however, and may be of any shape to provide sufficient volume for expansion and contraction of the coolant.

In other embodiments, the reservoir may be mounted elsewhere on the frame, for example, on the back surface of the solar concentrator. The reservoir may be mounted on a lower half of the frame, behind the solar concentrator. It may be oriented at an angle to prevent gas escaping into the cooling circuit, for example it may extend in the same or similar direction as the lower support arm.

The cooling system components may include more than one heat exchanger. The heat exchangers may be connected in series, in parallel or in a combination of series and parallel. Connecting the heat exchangers in parallel is preferred to connecting them in series, as this may result in a smaller pressure drop across the cooling circuit.

Where the frame includes a vertical axis and a horizontal axis, the cooling system components may include two heat exchangers located on either side of the vertical axis. The use of two heat exchangers rather than one may increase the heat extracted by the cooling system, and locating the heat exchangers either side of the vertical axis may balance the frame. The two heat exchangers may be aligned along the horizontal axis, and may be equidistant from the vertical axis. In this case, the heat exchangers may provide an additional benefit of moving the centre of gravity of the solar power generator closer towards the pivot point. This may provide better stability to the generator.

Examples of heat exchangers that may be used include a tube and fin radiator with, for example, half inch or other size copper tubes, or a 1 m×1 m (or larger) square radiator. The square radiator may have a single fan and the square shape may be created by bending the radiator. Of course it will be appreciated that other heat exchangers would also be appropriate for the system, and that the heat exchangers could be positioned at alternative locations on the frame, such as a heat exchanger below the pivot point and/or a heat exchanger above the pivot point.

In an embodiment, a pump and filter of the cooling system may be mounted on the frame, for example, adjacent to the reservoir. This may enable ease of access to these components to perform maintenance or repair work, as the components are located together and low on the frame. The pump and filter are often the components that more frequently require replacement or repair. The pump, for example, may be a 500 W, 150 litre per minute centrifugal pump.

The cooling circuit may include coolant flow paths through one or more support arms and the receiver. For example, where the frame has four support arms the coolant may flow up a lower support arm, through channels in the receiver and heatsinks on the back of the photovoltaic cells, down through two side support arms, through the heat exchangers and then back up to the receiver via the lower support arm. It will be appreciated that alternative flow paths may be used, depending on the location of the heat exchanger/s and reservoir.

### BRIEF DESCRIPTION OF THE DRAWINGS

Embodiments of the present invention will now be described, by way of example only, with reference to the accompanying drawings. It is to be understood that the particularity of the drawings does not supersede the generality of the preceding description of the invention.

FIG. 1 is a back perspective view of a prior art solar power generator having a cooling skid.

FIG. 2 is a perspective view of the cooling skid of FIG. 1.

FIG. 3 is a back perspective view of a solar power generator including a cooling system according to an embodiment of the invention.

FIG. 4 is a front view of the receiver shown in FIG. 3.

FIG. 5 is a perspective side view of the cooling system according to the embodiment of the invention, shown separately from other parts of the solar power generator.

FIG. 6 is a schematic plan view of the cooling system components.

FIG. 7 is a perspective view of a heat exchanger of the cooling system.

FIG. 8 is a side view of a reservoir of the cooling system.

FIG. 9 is a side cross sectional view of a solar power generator in a lowest position.

FIG. 10 is a side cross sectional view of a solar power generator in a highest position.

FIG. 11 is a side cross sectional view of the reservoir in three different orientations of the solar concentrator.

FIG. 12 is a side view portraying the angle of movement of a solar power generator about a horizontal axis.

FIG. 13 is another side view of the reservoir of the cooling system, shown without the frame of the solar power generator.

FIG. 14 is a plan view of controls and gauges of the cooling system.

### DETAILED DESCRIPTION

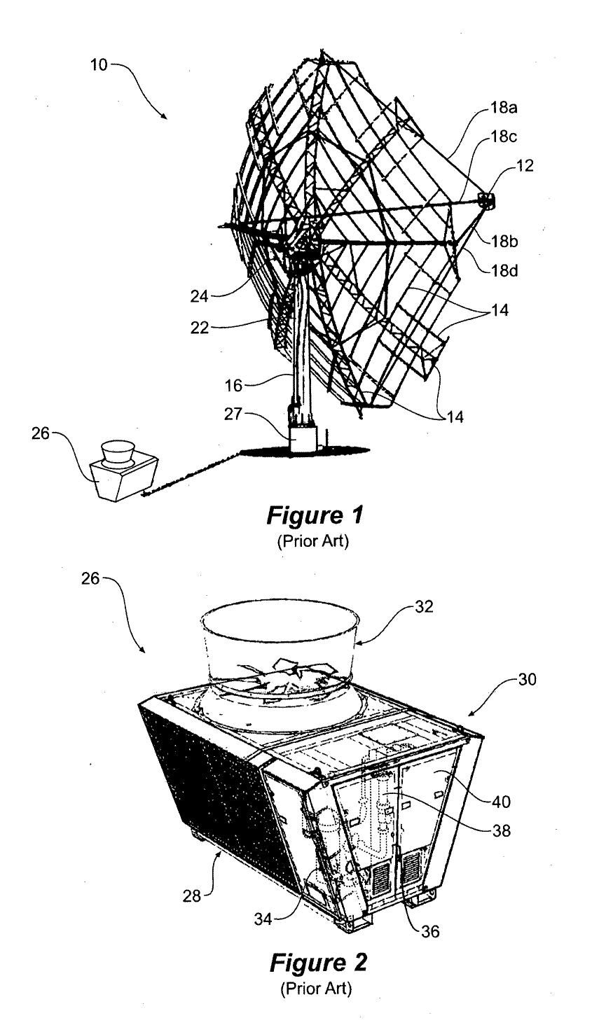

A prior art concentrated solar power generator 10 is shown in FIG. 1. The generator 10 includes a receiver 12 having photovoltaic cells that convert solar radiation into DC electrical energy, and a solar concentrator 14 in the form of a parabolic array of mirrors (mirrors not shown) that reflect solar radiation incident on the mirrors towards the receiver 12. The generator 10 also includes an electrical circuit (not shown) for the electrical energy output of the photovoltaic cells.

The concentrator mirrors are mounted on a frame 16. The frame 16 includes a mast 22 fixed into the ground, for supporting the solar concentrator 14 and a drive base 24 for pivoting the concentrator 14 about a vertical and horizontal axis in order to track the sun. The frame 16 further includes a series of four support arms 18a-18d for supporting the receiver 12 at a fixed position relative to the solar concentrator 14. The frame further includes radial trusses 20 extending radially out from the drive base 24 to the edge of the solar concentrator 14, for providing additional strength and stability to the concentrator 14.

The receiver 12 includes a coolant pathway (not shown), to cool the photovoltaic cells with a coolant such as water, in order to maintain a safe operating temperature and to maximise the performance (including operating life) of the photovoltaic cells. A cooling skid 26 contains all of the components for operating the cooling system. A cooling circuit runs from the cooling skid 26 to the base 27 of the mast 22 via a poly pipe assembly, then up to the drive base 24 via flexible hoses. Flexible hoses are needed to allow for rotation of the concentrator 14 when tracking the sun. The cooling circuit then extends across the back of the concentrator 14, along support arm 18a to the receiver 12, through the coolant pathway in the receiver 12, down support arm 18d and back to the cooling skid 26.

The cooling skid 26 is shown in more detail in FIG. 2. The components within the skid 26 include two radiators 28, 30, a fan 32 with a fan exit cowling, a reservoir (not shown), a pump and filter 34, a de-ioniser 36, a flow meter 38 and an electrical box 40. Heat from the receiver 12 is extracted from coolant running through the cooling circuit via the fan 32 blowing air through the radiators 28, 30. The cooling skid 26 is located metres from the frame 16.

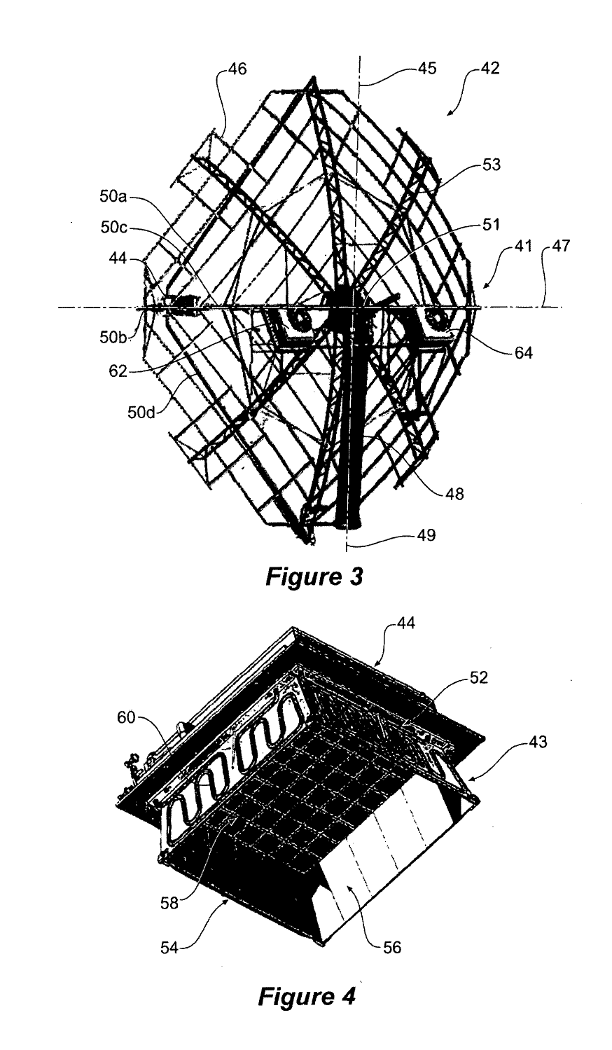

FIG. 3 shows a solar power generator 42 according to an embodiment of the invention. The generator 42 includes a receiver 44 that includes one or more photovoltaic cells for converting concentrated solar radiation into electrical energy, a solar concentrator 46 that includes an array of mirrors (not shown) for concentrating solar radiation on the receiver 44, a frame 48 on which the mirrors are mounted, the frame 48 including one or more support arms 50a-50d for supporting the receiver 44 relative to the solar concentrator 46, and a cooling system 41 including a cooling circuit for cooling the photovoltaic cells with a coolant, and cooling system components include a reservoir 70 (ref. FIG. 6) and heat exchangers 62, 64, wherein the reservoir 70 (ref. FIG. 6) and heat exchangers 62, 64 are mounted on the frame.

With reference to FIG. 4, the receiver 44 has a generally box-like structure. The receiver 44 also includes a solar flux modifier 43, which extends from a lower wall 52 of the box-like structure. The solar flux modifier 43 includes four panels 54 that extend from the lower wall 52 and converge toward each other. The solar flux modifier 43 also includes reflective surfaces 56 on the inwardly facing sides of the panels 54, for directing light onto the cells.

The receiver 44 includes a dense array of 2304 closely packed rectangular photovoltaic cells which are mounted to sixty four square modules 58. In the example, each module 58 includes 36 photovoltaic cells arranged in a 6 cell by 6 cell array. It will of course be appreciated that although the illustrated example includes sixty four square modules 58, with each module including thirty six photovoltaic cells arranged in a 6 cell by 6 cell array, other arrangements may be possible which include a different number of cells per module and/or a different number of modules per receiver. In the present case, the photovoltaic cells are mounted on each module 58 so that the photon source facing surface of the cell array is a mostly continuous surface. The modules 58 are mounted to the lower wall 52 of the box-like structure of the receiver 44.

Each module 58 includes a coolant flow path. The coolant flow path is an integrated part of each module 58 and allows coolant to be in thermal contact with the photovoltaic cells and extract heat from the cells. The coolant flow path of the modules 58 forms part of the cooling circuit. The cooling circuit also includes channels 60 on the flux modifier 43.

Returning again to FIG. 3, the frame 48 includes a mast 49 concreted into the ground and a drive base 51 for pivoting the concentrator 46 in order to track the sun. The drive base 51 in this embodiment is an altitude-azimuth or “alt-azimuth” tracking system that has two axes, a vertical axis 45, about which the system rotates to a desired azimuth measured eastwards from north, and a horizontal axis 47 (which itself rotates on the vertical axis), about which the system rotates to the desired altitude, i.e. angle above the horizon.

The support arms 50a-50d of the frame 48 include an upper support arm 50a, a lower support arm 50d, and two side support arms 50b and 50c. The support arms 50a-d are located around the concentrator 46 at 90 degrees apart, and extend from the frame 48 to the receiver 44 at an angle of about 45 degrees to a line extending from a middle of the frame, at the drive base 51, to the receiver 44. The frame 48 also includes radial trusses 53 extending radially out from the drive base 51 to the edge of the solar concentrator 46 to provide structural support to the concentrator 46.

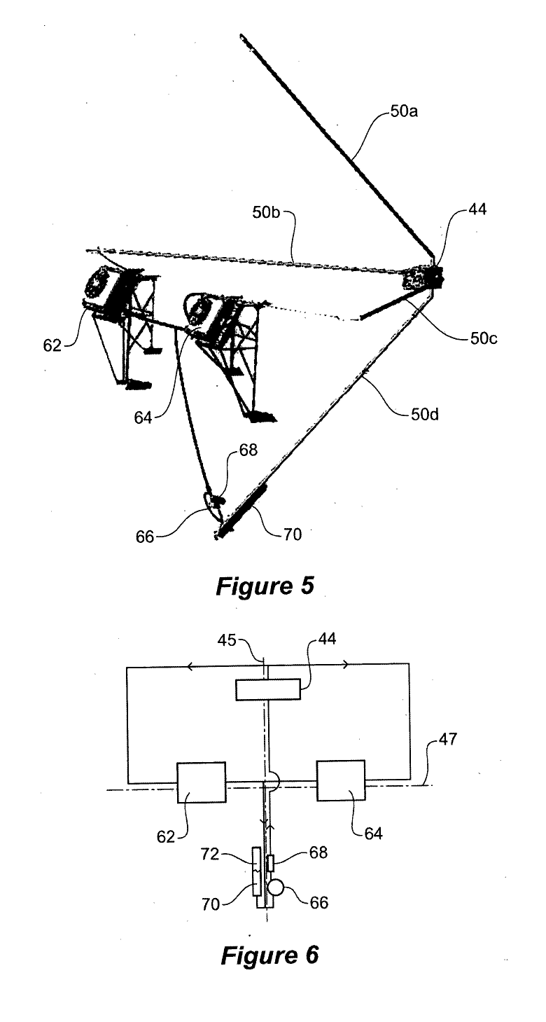

Components of the cooling system 41 are shown separately from the rest of the solar power generator 42 in their relative positions in FIG. 5 and schematically in FIG. 6. The components include the two heat exchangers 62, 64, a pump 66 and filter 68 and the reservoir 70. In FIG. 6, a nitrogen blanket 72 can be seen in the reservoir 70. The receiver 44 being cooled is also shown in FIGS. 5 and 6. FIG. 6 shows schematically the positions of the components relative to the vertical axis 45 and horizontal axis 47. The actual positions of these components on the frame 48 in this embodiment can be seen in FIG. 3.

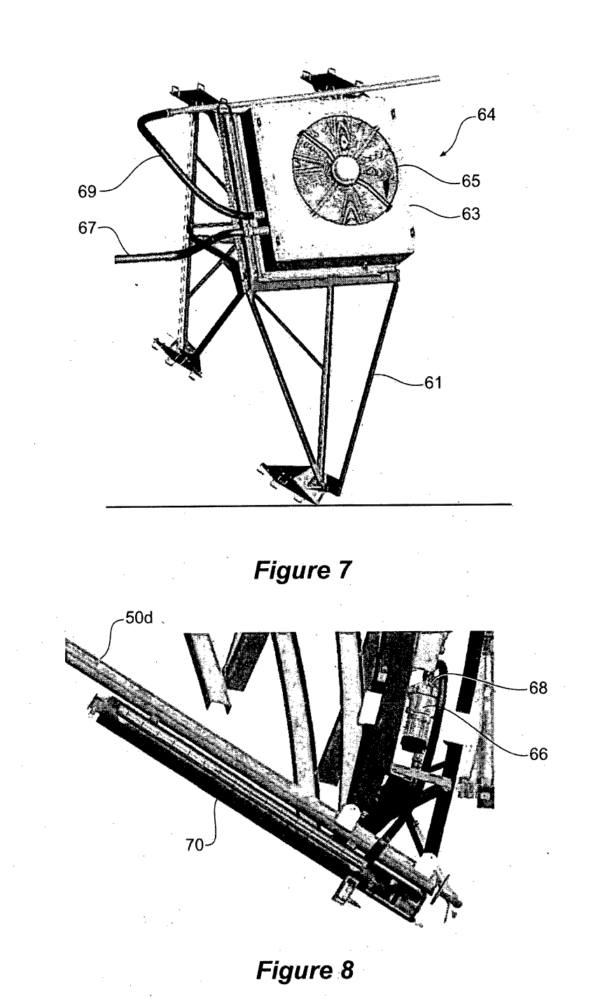

As shown in FIG. 3, the two heat exchangers 62, 64 are mounted on either side of the vertical axis 45, equidistantly from the vertical axis 45, and are aligned along the horizontal axis 47. This positioning of the heat exchangers 62, 64 assists in moving the centre of gravity of the frame 48 from a position on the receiver-side of the drive base 51, towards the drive base 51. This may provide better balance to the solar power generator 42. FIG. 7 is a closer view of a heat exchanger 64. The heat exchangers used in this embodiment are square 1 m×1 m copper tube radiators 63 with 500 W fans 65. FIG. 7 also shows piping 67 through which coolant enters the heat exchanger 64 and piping 69 through which coolant exits the heat exchanger 64 and moves towards the receiver 44. The heat exchanger 64 is attached to the frame 48 by a supporting structure 61. It will be appreciated that other heat exchangers could alternatively be used.

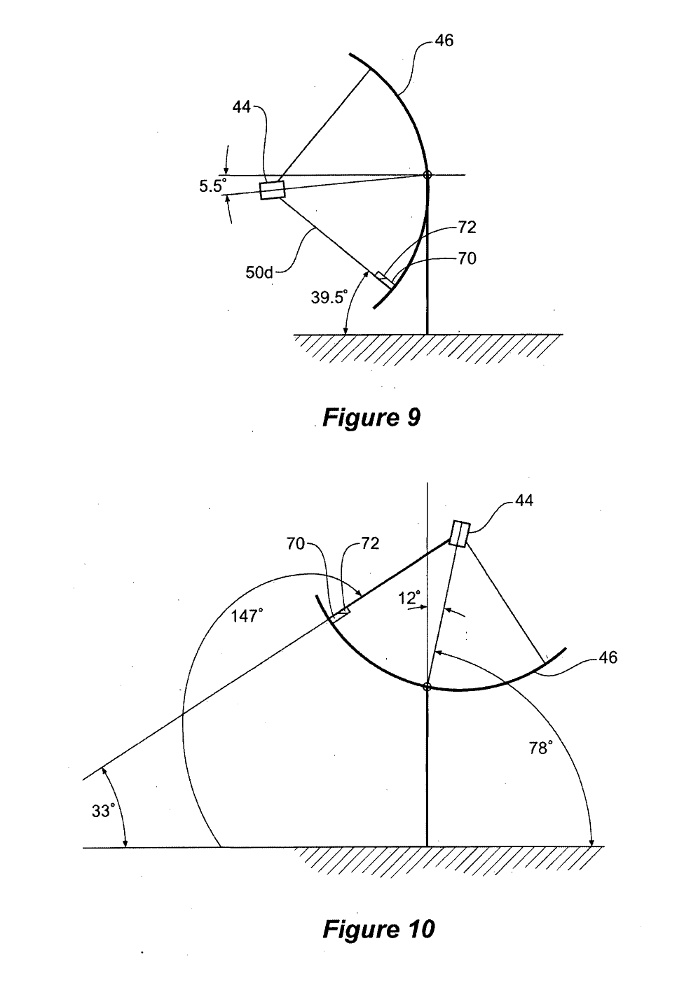

Referring now to FIG. 8, the reservoir 70 is mounted on the lower support arm 50d. The reservoir 70 in this embodiment is cylindrical and elongate, with a long axis of the reservoir 70 being parallel to the lower support arm 50d. Mounting the reservoir 70 on the lower support arm 50d may prevent a nitrogen blanket 72 (ref. FIG. 6) in the reservoir 70 from entering the cooling circuit. This will be explained further in connection with FIGS. 9-11.

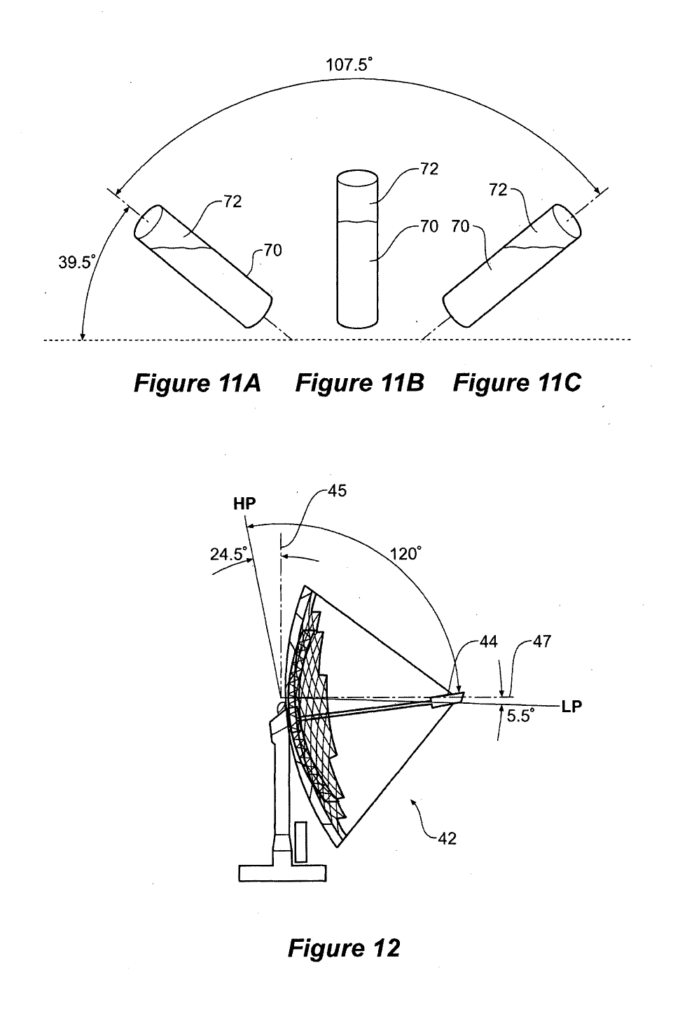

FIG. 9 shows the solar power generator 42 in a lowest position, with the solar concentrator 46 pointing towards the sun at a lowest tracked position in the sky. In this case, the solar concentrator 46 is pointing in a direction 5.5 degrees down from horizontal. In this position, the lower support arm 50d extends at an angle of 39.5 (45 subtract 5.5) degrees up from horizontal. The nitrogen blanket 72 in the reservoir 70 sits at the top of the reservoir at this angle, and does not enter the cooling circuit. The nitrogen level in this reservoir position is also illustrated in FIG. 11(a).

FIG. 10 shows the solar power generator 42 in a highest position, with the solar concentrator 46 pointing towards the sun at a highest tracked position in the sky. In this case, the solar concentrator 46 is pointing in a direction 12 degrees away from vertical (78 degrees up from horizontal). In this position, the lower support arm 50d extends at an angle of 57 (45 plus 12) degrees away from the vertical (33 degrees up from horizontal). Again, the nitrogen blanket in the reservoir 70 sits at the top of the reservoir at this angle, and does not enter the cooling circuit. The nitrogen level in this reservoir position is also illustrated in FIG. 11(c).

As illustrated in FIG. 11, nitrogen does not enter the cooling circuit despite rotation of the solar concentrator 46 and thus the reservoir 70 on the lower support arm 50d through a total angle of 107.5 degrees. By contrast, if the reservoir 70 was located on the upper support arm 50a or one of the side support arms 50b or 50c, there is a risk that at either the lowest or highest position shown in FIG. 9 or 10, nitrogen would enter the cooling circuit, and decrease the effectiveness of the cooling system 41.

It will be appreciated that in other embodiments, the range of movement of the solar concentrator 46 may differ. For example, the lowest position (LP) of the solar concentrator 46 may be pointing in a direction 5.5 degrees below horizontal and the highest position (HP) of the solar concentrator 46 may be pointing in a direction 24.5 degrees past vertical, giving a range of movement of 120 degrees. FIG. 12 shows this range of movement of the solar power generator 42 about the horizontal axis 47.

In different embodiments, the size and shape of the reservoir may be tailored to suit the range of movement of the solar concentrator, and the angle of the lower support arm.

Advantages may also be provided by using an elongate reservoir 70, rather than a shortened reservoir of the same volume. If the reservoir shortened reservoir had a wider dimension than the pipe connecting it to the cooling circuit, then as the solar concentrator 46 rotated, the level of the coolant may fall below the opening of the pipe, allowing nitrogen to enter the cooling circuit. An elongate reservoir 70 may avoid this problem.

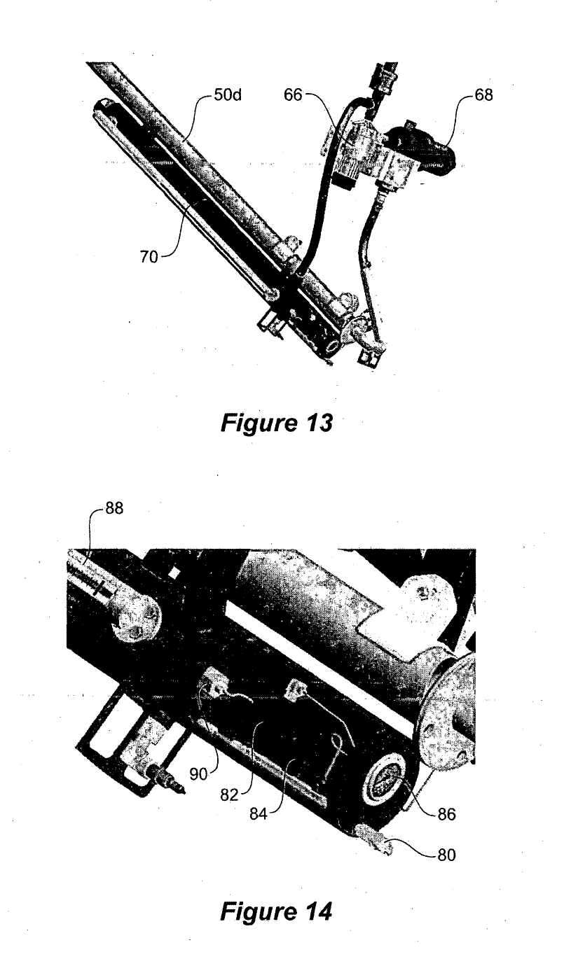

As can be seen in FIGS. 8 and 13, the pump 66 and filter 68 are mounted adjacent to the reservoir 70. The pump may be, for example, a 500 W, 150 LPM centrifugal pump. The positioning of the pump 66, filter 68 and reservoir 70 on a low part of the frame 48 enables easy access to these components for repair or replacement, when the solar concentrator 46 is in a low position. The pump 66 may be operated using electricity generated by photovoltaic cells in the receiver 44.

Controls and gauges of the cooling system are shown in FIG. 14. These include a nitrogen injector 80, for injecting nitrogen into the top of the reservoir 70 (an internal hose connects the nitrogen injector 80 to the top of the reservoir 70), a differential pressure switch 82 and a pressure transducer 84 for measuring pressure and setting off an alarm if the pressure is below or above an acceptable range. There is also a pressure release valve (not shown) located at the top of the reservoir 70. A pressure gauge 86 gives a visual indication of the pressure in the cooling system 41, and a level gauge 88 gives a visual indication of the level of coolant in the reservoir 70. The level gauge 88 also sets off an alarm if the level of coolant goes above or below an acceptable level. The controls and gauges also include a resistivity transmitter 90, which measures the conductivity/resistivity of the coolant in order to detect any impurities which may cause corrosion and alert an operator if the coolant needs changing.

To set up the cooling system 41, firstly the components are bolted on the frame 48. Then the cooling circuit is filled with water through a fill and drain port on the reservoir 70 or another location in the cooling system 41. The cooling circuit is then checked to ensure that there are no leaks. After this, nitrogen is injected into the top of the reservoir 70 using nitrogen injector 80. This increases the pressure in the cooling circuit and reduces the level of coolant in the reservoir 70. Water is bled from the system until a desired level of coolant and a desired pressure in the cooling circuit is achieved. Glycol, which acts as an anti-freeze, and corrosion inhibitors are then added to the water and the level of coolant and pressure of the cooling circuit are adjusted again if necessary. Finally, the electronic components in the reservoir 70, the pump 66 and the fans of the heat exchangers 62, 64 are connected to an electrical box with cabling.

In use of the cooling system 41, the coolant is pumped using the pump 66 up a coolant flow path in the lower support arm 50d and through coolant flow paths in the receiver 44 to extract heat from the photovoltaic cells. The coolant then moves down coolant flow paths in the side support arms 50b and 50c, through the heat exchangers 62, 64 on the back of the solar concentrator 46, where heat is extracted from the coolant, and then back up to the receiver 44 through the coolant flow path in the lower support arm 50d.

As described above, the cooling system 41 has a number of controls and gauges to check the pressure and coolant level of the cooling system 41, and to check the coolant purity. If problems are identified, an alarm is activated and an operator can make adjustments as necessary. For maintenance, the cooling system 41 may also be regularly bled, to make sure that air has not become entrapped in the cooling circuit. Entrapped air may mix with glycol, causing it to become corrosive, or may cause turbulence in the coolant, thus eroding the system.

It can be seen that the cooling system 41 has advantages over the prior art cooling system shown in FIGS. 1 and 2. A separate cooling skid 26 is not needed, nor are the poly pipe assemblies and flexible hoses connecting the cooling skid to the drive base 24. This may reduce the cost of the cooling system. Further, because all parts of the cooling system 41 of the described embodiment are stationary relative to each other, flexible hoses (which are subject to wear and may require replacement) are not required. Locating the cooling system 41 on the frame 48 enables smaller, less expensive and less power consumptive components to be used.

It is to be understood that various alterations, additions and/or modifications may be made to the parts previously described without departing from the ambit of the present invention, and that, in the light of the above teachings, the present invention may be implemented in a variety of manners as would be understood by the skilled person.

1. A solar power generator including:
a receiver that includes one or more photovoltaic cells for converting concentrated solar radiation into electrical energy,
a solar concentrator that includes an array of mirrors for concentrating solar radiation on the receiver,
a frame on which the mirrors are mounted, the frame including one or more support arms for supporting the receiver relative to the solar concentrator, and
a cooling system including a cooling circuit for cooling the photovoltaic cells with a coolant, and cooling system components including a reservoir and one or more heat exchangers, wherein the reservoir and one or more heat exchangers are mounted on the frame.

2. A solar power generator as claimed in claim 1, wherein the support arms for supporting the receiver include a lower support arm and the reservoir is mounted on the lower support arm.

3. A solar power generator as claimed in claim 2, wherein the lower support arm extends from a lower part of the frame to the receiver at an angle of about 45 degrees to a line extending from a middle of the frame to the receiver.

4. A solar power generator as claimed in claim 2, wherein the reservoir is elongate, with a long axis of the reservoir being parallel to the lower support arm.

5. A solar power generator as claimed in claim 1, wherein the cooling system components include more than one heat exchanger.

6. A solar power generator as claimed in claim 5, wherein the frame includes a vertical axis and a horizontal axis about which the solar concentrator is rotatable and the cooling system components include two heat exchangers, located on either side of the vertical axis.

7. A solar power generator as claimed in claim 6, wherein the two heat exchangers are aligned along the horizontal axis.

8. A solar power generator as claimed in claim 6, wherein the two heat exchangers are equidistant from the vertical axis.

9. A solar power generator as claimed in claim 1, wherein the cooling system components further include a pump and filter mounted on the frame.

10. A solar power generator as claimed in claim 9, wherein the pump and filter are mounted adjacent to the reservoir.

11. A solar power generator as claimed in claim 1, wherein the cooling circuit includes coolant flow paths through one or more support arms and the receiver.

12. A method of installing a cooling system for a solar power generator including a receiver that includes one or more photovoltaic cells for converting concentrated solar radiation into electrical energy, a solar concentrator that includes an array of mirrors for concentrating solar radiation on the receiver, and a frame on which the mirrors are mounted, the frame including one or more support arms for supporting the receiver in a fixed position relative to the solar concentrator, the method including:
mounting a reservoir on the frame,
mounting one or more heat exchangers on the frame, and
connecting these components with a cooling circuit for cooling the photovoltaic cells with a coolant.

13. A method as claimed in claim 12, wherein the reservoir is mounted on a lower support arm of the frame support arms.

14. A method as claimed in claim 13, wherein the reservoir is elongate and mounted so that a long axis of the reservoir is parallel to the lower support arm.

15. A method as claimed in claim 12, wherein mounting one or more heat exchangers on the frame includes mounting two heat exchangers on either side of a vertical axis of the frame.

16. A method as claimed in claim 15, wherein the two heat exchangers are equidistant from the vertical axis.

17. A method as claimed in claim 15, wherein two heat exchangers are aligned along a horizontal axis of the frame.

18. A method as claimed in claim 12, further including mounting a pump and filter on the frame.

19. A method as claimed in claim 18, wherein mounting a pump and filter on the frame includes mounting the pump and filter near the reservoir.
